(19) United States
(12) Patent Application Publication
(10) Pub. No.: US 2009/0200535 A1
(43) Pub. Date: Aug. 13, 2009

(54) Non-Volatile Memory Element with Improved Temperature Stability

(76) Inventor: Klaus-Dieter Ufert, Unterschleissheim (DE)

Correspondence Address: SLATER & MATSIL, L.L.P., 17950 PRESTON ROAD, SUITE 1000, DALLAS, TX, 75252, US

(21) Appl. No.: 12/030,070

(22) Filed: Feb. 12, 2008

(51) Int. Cl. H01L 45/00

(52) U.S. Cl. 257/3; 438/54; 257/E45.002; 257/E21.645

(57) ABSTRACT

An integrated circuit including a memory element is described. The memory element includes a solid electrolyte layer that includes a matrix material having a metal dissolved therein, and a dopant distributed in the matrix material, the dopant competing with the metal to bind with elements of the matrix material at a crystallization temperature so that at least a portion of the metal in the matrix material remains unbound, to increase the temperature stability of the memory element.

### BACKGROUND

Non-volatile memory retains its stored data even when power is not present. This type of memory is used in a wide variety of electronic equipment, including digital cameras, portable audio players, wireless communication devices, personal digital assistants, and peripheral devices, as well as for storing firmware in computers and other devices.

Non-volatile memory technologies include flash memory, magnetoresistive random access memory (MRAM), phase change random access memory (PCRAM), and conductive bridging random access memory (CBRAM). Due to the great demand for non-volatile memory devices, researchers are continually improving non-volatile memory technology, and developing new types of non-volatile memory.

### SUMMARY OF THE INVENTION

In accordance with an embodiment of the invention, a memory element includes a solid electrolyte layer that includes a matrix material having a metal dissolved therein, and a dopant distributed in the matrix material, the dopant competing with the metal to bind with elements of the matrix material at a crystallization temperature so that at least a portion of the metal in the matrix material remains unbound, to increase the temperature stability of the memory element.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B show a conductive bridging memory element;

FIGS. 2A-2C show views of the formation of a conductive bridge in a conductive bridging memory element.

FIGS. 3A and 3B show alternative block diagram layouts of a memory cell using a conductive bridging memory element;

FIGS. 4A and 4B are block diagrams showing materials formed during a sample annealing process in a conventional conductive bridging memory element, and in a conductive bridging memory element according to an embodiment of the invention, respectively;

FIG. 5 shows a conductive bridging memory element in accordance with an embodiment of the invention;

FIG. 6 is a block diagram of a method for fabricating a conductive bridging memory element in accordance with an embodiment of the invention;

FIGS. 7A and 7B show, respectively, a cross section of a memory device in accordance with an embodiment of the invention, and a schematic representation of two memory cells configured as shown in the cross section;

FIGS. 8A-8G show steps in the formation of a bottom contact that may be used (as shown in FIG. 8G) with a conductive bridging memory element in accordance with an embodiment of the invention;

FIG. 9 is a block diagram of a method of storing information in accordance with an embodiment of the invention;

FIG. 10 shows an example computing system including a memory device using memory cells in accordance with an embodiment of the invention; and

FIGS. 11A and 11B show a memory module that may include a memory device according to an embodiment of the invention.

### DETAILED DESCRIPTION OF ILLUSTRATIVE EMBODIMENTS

The scale of electronic devices is constantly being reduced. For memory devices, conventional technologies, such as flash memory and DRAM, which store information based on storage of electric charges, may reach their scaling limits in the foreseeable future. Additional characteristics of these technologies, such as the high switching voltages and limited number of read and write cycles of flash memory, or the limited duration of the storage of the charge state in DRAM, pose additional challenges. To address some of these issues, researchers are investigating memory technologies that do not use storage of an electrical charge to store information. One such technology is conductive bridging random access memory (CBRAM).

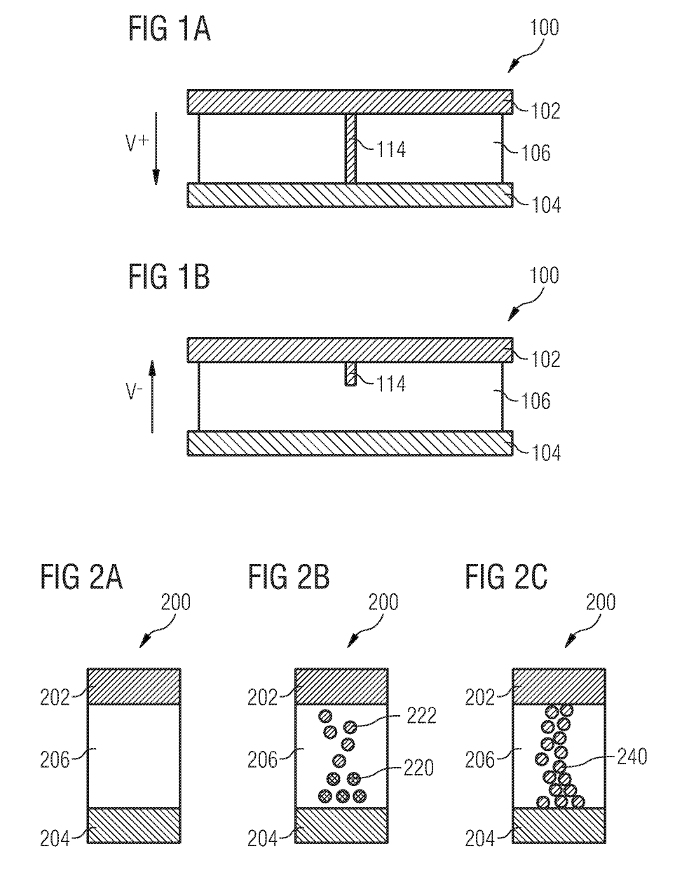

FIG. 1A shows a conventional conductive bridging junction (CBJ) for use in a CBRAM cell. A CBJ 100 includes a first electrode 102, a second electrode 104, and a solid electrolyte block 106 sandwiched between the first electrode 102 and the second electrode 104. One of the first electrode 102 and the second electrode 104 is a reactive electrode, the other is an inert electrode. In this example the first electrode 102 is the reactive electrode, and the second electrode 104 is the inert electrode. The first electrode 102 includes silver (Ag) in this example, and the solid electrolyte block 106 includes a silver-doped chalcogenide glass material.

When a voltage is applied across the solid electrolyte block 106, a redox reaction is initiated that drives Ag+ ions out of the first electrode 102 into the solid electrolyte block 106 where they are reduced to Ag, thereby forming Ag rich clusters within the solid electrolyte block 106. The size and the number of Ag rich clusters within the solid electrolyte block 106 may be increased to such an extent that a conductive bridge 114 between the first electrode 102 and the second electrode 104 is formed.

As shown in FIG. 1B, when an inverse voltage to that applied in FIG. 1A is applied across the solid electrolyte 106, a redox reaction is initiated that drives Ag+ ions out of the solid electrolyte block 106 into the first electrode 102 where they are reduced to Ag. As a consequence, the size and the number of Ag rich clusters within the solid electrolyte block 106 is reduced, thereby reducing, and eventually removing the conductive bridge 114.

To determine the current memory state of the CBJ 100, a sensing current is routed through the CBJ 100. The sensing current encounters a high resistance if no conductive bridge 114 exists within the CBJ 100, and a low resistance when a conductive bridge 114 is present. A high resistance may, for example, represent “0”, while a low resistance represents “1”, or vice versa.

The solid electrolyte block 106 can include many materials, but the materials of greatest interest for use in CBRAM are the chalcogens, including oxygen (O), sulfur (S), and selenium (Se). Combining these with copper (Cu) or silver (Ag) yields binary electrolytes, such as Ag₂Se or Cu₂S. Alternatively, a transition metal, such as tungsten (W) can be reacted with oxygen to form a suitable base glass for an electrolyte. If, for example, the resulting tungsten oxide is sufficiently porous and in its trioxide form (WO₃), silver or copper ions will be mobile within the material, and can form electrodeposits. Another approach is to combine chalcogens with other elements, such as germanium, to create a base glass into which Cu or Ag may be dissolved. An example of such an electrolyte is Ag dissolved in Ge₃₀Se₇₀ (e.g., Ag₃₃Ge₂₀Se₄₇). This takes the form of a continuous glassy Ge₂Se₃ backbone and a dispersed Ag₂Se phase, which is superionic and allows the electrolyte to exhibit superionic qualities. The nanostructure of this material, and of its sulphide counterpart, provide good characteristics for use in switching devices, such as CBRAM. The metal-rich phase is both an ion and an electron conductor, but the backbone material that separates each of these conducting regions is a good dielectric, so the overall resistance of the material prior to electrodeposition is high. Generally, a germanium selenide (GeSe) compound or germanium sulfide (GeS) compound is used in conventional CBRAM devices, but silicon selenide and silicon sulfide may also be used. Although the example embodiments of the invention below are generally described in terms of a GeS device, it will be understood that the principles of the invention may be employed in CBRAM devices that use GeSe, silicon selenide or sulfide, or other suitable solid electrolyte materials.

A solid electrolyte, such as those used in CBRAM, can be made to contain ions throughout its thickness. The ions nearest the electron-supplying cathode will move to its surface and be reduced first. Non-uniformities in the ion distribution and in the nano-topography of the electrode will promote localized deposition or nucleation. Even if multiple nuclei are formed, the one with the highest field and best ion supply will be favored for subsequent growth, extending out from the cathode as a single metallic nanowire. The electrodeposition of metal on the cathode physically extends the electrode into the electrolyte, which is possible in solid electrolytes, particularly if they are amorphous or partially amorphous, and are able to accommodate the growing electrodeposit in a void-rich, semi-flexible structure.

Because the electrodeposit is connected to the cathode, it can supply electrons for subsequent ion reduction. This permits the advancing electrodeposit to harvest ions from the electrolyte, plating them onto its surface to extend itself forward. Thus, in an electrolyte containing a sufficient percentage of metal ions, the growing electrodeposit is always adjacent to a significant source of ions, so the average distance each ion travels in order to be reduced is, at most, a few nm.

The resistivity of the electrodeposit is orders of magnitude lower than that of the surrounding electrolyte, so once the electrodeposit has grown from the cathode to the anode, forming a complete conductive bridge, the resistance of the structure drops considerably. The decreasing resistance of the structure due to the electrodeposition effect increases the current flowing through the device until the current limit of the source is reached. At this point, the voltage drop falls to the threshold for electrodeposition, and the process stops, yielding the final “on” resistance of the structure.

As noted above, the electrodeposition process is reversible by changing the polarity of the applied bias. If the electrodeposit is made positive with respect to the original oxidizable electrode, it becomes the new anode, and will dissolve via oxidation. During the dissolution of the conductive bridge, balance is maintained by electrodeposition of metal back into the place where the excess metal for the electrodeposition originated. The original growth process of the conductive bridge will have left a low ion density region in the electrolyte surrounding the electrode, and this “free volume” will favor redeposition without extended growth back into the electrolyte. Once the electrodeposit has been completely dissolved, the process will self-terminate, yielding the final “off” resistance of the structure. The asymmetry of the structure facilitates the cycling of the device between a high-resistance “off” state, and a low-resistance “on” state, permitting the device to operate as a switch or memory element.

FIGS. 2A-2C show another view of this process. In FIG. 2A, a CBRAM element 200, including a top electrode 202, a bottom electrode 204, and a solid electrolyte 206 is in its high-resistivity state, in which no conductive bridge is formed within the solid electrolyte. In this example, the solid electrolyte 206 may be any suitable material, such a GeS material, into which Ag has been dissolved. The top electrode 202 includes silver, and is the “reactive” electrode. The bottom electrode 204 is the “inert” electrode, and includes a suitable conductive material, such as W.

In FIG. 2B, a transition state is shown, in which a voltage is applied between the top electrode 202 and the bottom electrode 204. This causes the movement of electrons 220 and Ag-ions 222 within the solid electrolyte 206, to form a conductive bridge.

In FIG. 2C, the CBRAM element 200 is in its low-resistivity state, in which an Ag conductive bridge 240 has been formed. By applying a voltage having a polarity opposite of the voltage used to form the Ag conductive bridge 240, the CBRAM element can again enter the transition state shown in FIG. 2B, to remove the conductive bridge 240. Thus, the CBRAM element 200 can be selectively transitioned between the high-resistivity state shown in FIG. 2A and the low-resistivity state shown in FIG. 2C through the application of appropriate voltages between the top electrode 202 and the bottom electrode 204.

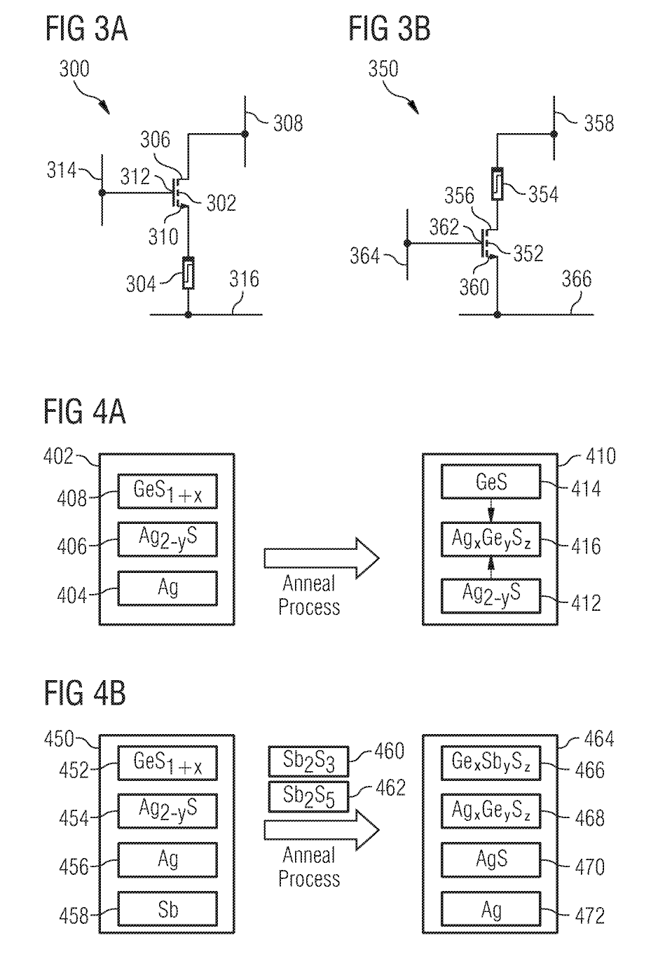

FIG. 3A shows an illustrative memory cell that uses a memory element such as the CBJ shown in FIGS. 1A-1B or a memory element in accordance with the invention, as described hereinbelow. The memory cell 300 includes a select transistor 302 and a memory element 304. The select transistor 302 includes a source 306 that is connected to a bit line 308, a drain 310 that is connected to the memory element 304, and a gate 312 that is connected to a word line 314. The memory element 304 is also connected to a common line 316, which may be connected to ground, or to other circuitry, such as circuitry (not shown) for determining the resistance of the memory cell 300, for use in reading. Alternatively, in some configurations, circuitry (not shown) for determining the state of the memory cell 300 during reading may be connected to the bit line 308. It should be noted that as used herein the terms connected and coupled are intended to include both direct and indirect connection and coupling, respectively.

To write to the memory cell, the word line 314 is used to select the cell 300, and a current on the bit line 308 is forced through the memory element 304, to form or remove a conductive bridge in the memory element 304, changing the resistance of the memory element 304. Similarly, when reading the cell 300, the word line 314 is used to select the cell 300, and the bit line 308 is used to apply a voltage across the memory element 304 to measure the resistance of the memory element 304.

The memory cell 300 may be referred to as a 1T1J cell, because it uses one transistor, and one memory junction (the memory element 304). Typically, a memory device will include an array of many such cells. It will be understood that other configurations for a 1T1J memory cell, or configurations other than a 1T1J configuration may be used with a CBRAM memory element such as is shown in FIGS. 1A and 1B, or a memory element in accordance with the invention, as described hereinbelow. For example, in FIG. 3B, an alternative arrangement for a 1T1J memory cell 350 is shown, in which a select transistor 352 and a memory junction 354 have been repositioned with respect to the configuration shown in FIG. 3A.

In the alternative configuration shown in FIG. 3B, the memory element 354 is connected to a bit line 358, and to a source 356 of the select transistor 352. A drain 360 of the select transistor 352 is connected to a common line 366, which may be connected to ground, or to other circuitry (not shown), as discussed above. A gate 362 of the select transistor 352 is controlled by a word line 364.

One challenge presented by the use of amorphous or partially amorphous solids such as GeS glasses in CBRAM devices is the poor temperature stability of such materials. In particular, these materials may start to change from an amorphous or partially amorphous phase to a crystal phase at temperatures as low as 250° C. to 280° C. In a crystal phase, the migration of ions in the material becomes more difficult, which can lead to failure of the memory device. The temperatures reached during the back-end-of-line (BEOL) CMOS process may be as high as 400° C., or higher. These temperatures are too high for the chalcogenide glasses that are used in conventional CBRAM devices. Attempts to improve the temperature stability of CBRAM devices by doping with oxygen have resulted in devices in which the Ag ions have insufficient ability to diffuse through the matrix, leading to devices that may be unable to retain an on-state.

One cause of this poor temperature stability in devices that use GeS is thought to be the presence of excess sulfur in the solid electrolyte. At higher temperatures, such as those found during a typical BEOL CMOS process, the amorphous GeS matrix, having a GeS₁₊ₓ composition will increasingly form crystallization seeds in the form of a Ge/S lattice. The GeS₂ phase is in this case less stable (T_{melting} 515° C.) and more complex, and cannot be formed with regard to the GeS phase. Thus, sulfur becomes free, and increasingly binds with the Ag that has been dissolved into the glass. Depending on the Ag doping concentration and the amount of sulfur, AgS and GeS₁₊ₓ can go into various compositions with each other. In the amorphous matrix, Ag exists in an unbound form, and in the form of AgS clusters. As the increased temperature leads to increasing amounts of free sulfur, the unbound Ag atoms will combine with the free sulfur to form AgS or Ag₂S (at higher temperatures), which in turn can go into a common composition with GeS. This increasingly crystalline matrix, containing AgS/Ag₂S clusters and compositions of AgₓGe_{y}S_{z} (in various compositions), requires increased switching voltages, so that switching of a memory element may no longer occur at the typical 0.2V programming voltage.

The optimal amount of sulfur in the layer for switching and temperature characteristics is difficult to determine, and difficult to control. Just as too much unbound sulfur may cause difficulties, as discussed above, so may too little sulfur. For example, in the case of an amorphous GeS matrix having a Ge to S ratio near 1:1, too little free unbound sulfur is available to permit sufficient formation of AgS clusters. Some formation of AgS clusters is desirable to facilitate switching, and insufficient sulfur to form such AgS clusters may result in poor switching characteristics.

In accordance with the invention, CBRAM having improved temperature stability may be provided by doping the solid electrolyte with an additional material that has the ability to bind sulfur in “competition” with Ag, so that excess sulfur is bound, while still permitting sufficient formation of AgS clusters. This can be achieved, for example, by doping with indium (In), tin (Sn), or antimony (Sb). Doping with such a material should cause the excess free sulfur to be bound (in part) to the doping atoms, and at higher temperatures should hinder the formation of additional Ag_{2-y}S and the composition of Ag_{2-y}S and GeS/S₂ to a mixture phase of AgGeS. Additionally, these materials can go into common sulfur composition with Ge, to form, for example, GeSbS, reducing additional binding possibilities for Ag. Additionally, doping with such materials should have only minor effects on the switching characteristics of a CBRAM device, which should be substantially determined by the Ag/Ag+/AgS in the system, and only to a slight degree by the change in germanium, dopant, and sulfur compounds in the matrix.

Doping with Sb, Sn, or In is particularly effective in binding free sulfur at high temperature, since these dopants can bind at least 1.5 sulfur atoms. Sb, for example, can bind sulfur in an Sb₂S₃ configuration, or an Sb₂S₅ configuration at higher temperature. Thus, the excess formation of AgS clusters from free Ag atoms and the seed formation or crystallization of the AgGeS matrix is hindered. At lower temperatures, such as after cooling to Tr (room temperature) in a BEOL anneal process, the Sb₂S₅ configuration may no longer be stable, so that some reorganization of the sulfur may occur. However, at low temperatures (such as Tr), this will only result in low energetic agglomerations, which will not substantially affect switching of a CBRAM device.

The effects of doping with a material such as Sn, Sb, or In, in accordance with the invention, during an example CBRAM anneal process are illustrated in FIGS. 4A-4B. In FIG. 4A, a solid electrolyte matrix 402 at temperature Tr includes Ag 404, Ag_{2-y}S compounds 406, and GeS₁₊ₓ compounds 408. When the temperature of the solid electrolyte matrix 402 is increased during the anneal process, with an excess of mobile S, the free Ag is bound, and seed formation occurs. The resulting matrix 410 has Ag_{2-y}S compounds 412, GeS 414, and AgₓGe_{y}S_{z} compounds 416, and much of the free Ag has been bound in the Ag_{2-y}S compounds 412 and AgₓGe_{y}S_{z} compounds 416, hindering switching.

In FIG. 4B, a similar example anneal process is shown, in which a solid electrolyte matrix 450 has been doped with Sb. Thus, the solid electrolyte matrix at temperature Tr contains GeS₁₊ₓ compounds 452, Ag_{2-y}S compounds 454, Ag 456, and Sb 458. When the temperature is increased during the anneal process, the excess sulfur is bound with the Sb, to form Sb₂S₃ 460 and Sb₂S₅ 462, in competition with binding with Ag. Thus, the formation of Ag compositions is reduced. The resulting matrix 464 includes GeₓSb_{y}S_{z} compounds 466, AgₓGe_{y}S_{z} compounds 468, AgS 470 and Ag 472. As a result of the reduced formation of Ag compounds at high temperatures, switching in the resulting matrix 464 is not substantially hindered.

While the example shown in FIGS. 4A and 4B uses Sb as the dopant for increasing the temperature stability of a CBRAM device, it will be understood that other materials, including Sn and In could be used in a similar manner. In accordance with embodiments of the invention, a dopant that will bind the sulfur that is unbound at higher temperatures in order to hinder the additional formation of AgS/Ag₂S or AgGeS compositions may be used to increase the temperature stability of a CBRAM device. Preferably, such a dopant material can bind excess sulfur, can go into a reaction with GeS, and has at least similar reaction times with the matrix materials as Ag at similar temperatures, so that the dopant will “compete” with Ag to bind with the excess sulfur and other matrix materials. By using such a dopant, it should be possible to increase the temperature stability into the range of 350 to 400° C., or possibly higher, which should be sufficient to survive many BEOL processes.

FIG. 5 shows an example embodiment of a CBJ 500 in accordance with the invention. The CBJ 500 includes a top contact 502, a solid electrolyte layer 504, and a bottom contact 506. The top contact 502 in this example is the “reactive” electrode, and preferably includes Ag. The bottom contact 506 is the “inert” electrode, and may include a suitable conductive material, such as W. The solid electrolyte layer 504 includes a GeS matrix 508, having Ag 510 dissolved therein. Additionally, in accordance with the invention, the solid electrolyte layer 504 includes a dopant material 512 such as Sb, Sn, or In, which will bind excess sulfur in competition with the Ag 510 at higher temperatures, improving the temperature stability of the CBJ 500. The concentration of this dopant is preferably in the range of approximately 1% to approximately 5%, but other concentrations are possible, and may serve a similar purpose.

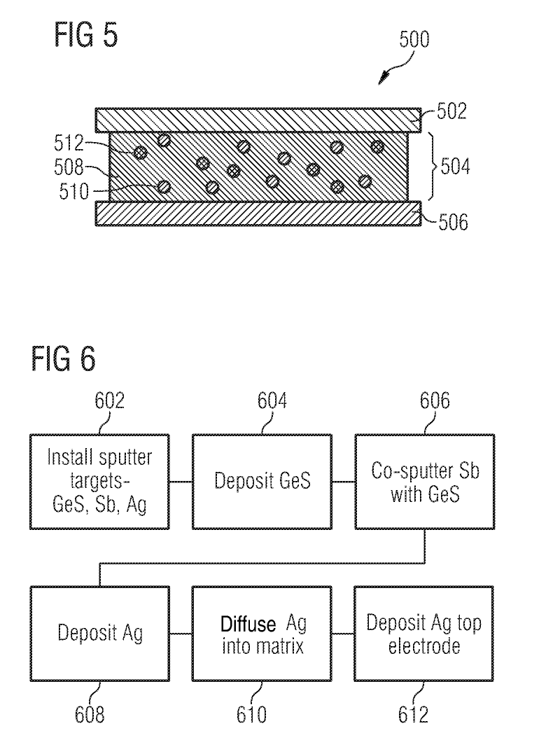

Referring now to FIG. 6, an example of a method of manufacturing a CBRAM memory element in accordance with an embodiment of the invention is described. It will be understood that the manufacturing of such a memory element may be accomplished by any method known in the art or hereafter developed that is suitable for forming the inventive structure. Additionally, although the method describes use of Sb as a dopant to improve the temperature stability of the CBRAM device, it will be understood that other materials, such as Sn or In could be used.

As described, the method starts with wafers onto which select transistors, vias, an isolation layer, and bottom electrode (typically containing W) have already been deposited using conventional techniques. Thus, the method described with reference to FIG. 6 shows only the manufacture of the doped solid electrolyte, and deposition of the top (reactive) electrode. Advantageously, the manufacture of a doped solid electrolyte layer in accordance with the invention can be achieved without substantially altering the flow of the process or the equipment used in the manufacture of conventional CBRAM memory elements.

In step 602, a GeS target, an Sb target, and an Ag target are installed in sputter equipment that is capable of using at least three sputter targets without disrupting the vacuum. Many commonly used sputter deposition devices, such as some of the models manufactured by Canon ANELVA Corporation, of Tokyo, Japan, KDF Electronics, of Rockleigh, N.J., and ULVAC Technologies, Inc., of Methuen, Mass. have this capability.

In step 604, a GeS layer is deposited. This layer may be deposited by means of RF-magnetron sputtering of a GeS-compound target, or other suitable sputtering techniques. In the case of RF-magnetron sputtering, typically Ar is used as a sputter gas, at a pressure of approximately 4.5×10⁻³ mbar and an HF-sputter power in the range of 1 to 2 kW. In some embodiments, this layer is deposited into pre-manufactured vias or on a W-plug of the memory element, and may have a thickness of approximately 40 to 45 nm, though a different thickness may be used.

In step 606, at the same time that the GeS layer is being deposited in step 604, the doping material for the GeS matrix is sputtered with a corresponding rate by means of co-sputtering from an Sb target. This can be done using, for example, DC sputtering with a power in the range of 500 W. Because this co-sputtering is occurring simultaneously with the sputtering of the GeS, the pressure is identical. Where Sb is used as the doping material, a concentration of Sb in the range of approximately 1% to approximately 5% is preferred, though other concentrations may be used.

In step 608, Ag is deposited on the Sb doped GeS layer, and in step 610, the Ag is diffused into the matrix by, for example, photodiffusion.

In step 612, the memory element is completed by depositing the Ag top electrode. This may be done, for example, by DC magnetron sputtering from an Ag target in a noble gas. In some embodiments, a TaN hard mask may then be deposited on the top electrode, and the CBRAM device may be completed using conventional techniques.

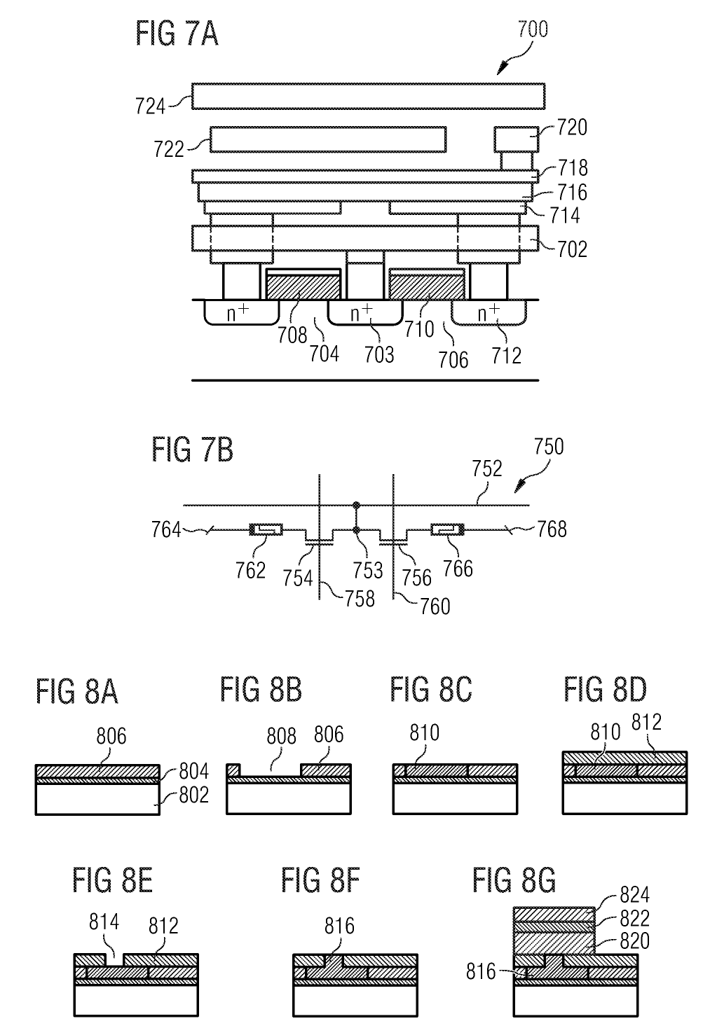

Referring to FIG. 7A, a cross section 700 of two cells of a CBRAM device is shown. While the cross section 700 provides an integration scheme that would be suitable for use with a CBRAM device according to the present invention, it may also be used for conventional CBRAM devices. Similarly, a CBRAM memory element according to the invention is not limited to use in a device such as is shown in FIG. 7A, but may be used in any CBRAM device.

In the cross section 700 shown in FIG. 7A, a bit line 702 is connected to a common source 703 for the select transistors 704 and 706 of two memory cells. The gates of the transistors 704 and 706 are controlled by word lines 708 and 710, respectively. Examining just one of the cells (the other is substantially identical), the drain 712 of the select transistor 706 is connected to a bottom contact 714, which contacts a solid electrolyte 716, which may be a GeS matrix into which Ag has been dissolved, doped with Sb, Sn, In, or another suitable material to increase temperature stability in accordance with the invention. Above the solid electrolyte 716, an Ag-rich plate 718 has been deposited. The Ag-rich plate is connected to a common line 720. The same metal layer that includes the connection to the common line 720 may also include other connections, such as a segmented word line connection 722. A top metal layer 724 may carry power for the device, or be used for other purposes on an integrated device.

In a device having a layout as shown in the cross section 700, the word line pitch and the bit line pitch may be equal, and may be approximately twice the feature size. Using a technology that provides a feature size of 90 nm, this means that the bit line and word line pitch would be approximately 180 nm.

In FIG. 7B, a schematic 750 for the memory cells shown in the cross section 700 of FIG. 7A is shown. In the schematic 750, a bit line 752 is connected to a common source 753 for transistors 754 and 756. Word lines 758 and 760 control gates of transistors 754 and 756, respectively. The transistor 754 is connected to a CBRAM memory element 762, and to a common line 764, while the transistor 756 is connected to a CBRAM memory element 766 and a common line 768 (which may be the same as the common line 764). The CBRAM memory elements 762 and 766 include a solid electrolyte that has been doped with Sb, Sb, In, or another suitable material to increase temperature stability, in accordance with an embodiment of the invention.

Referring to FIGS. 8A-8G, example steps in a process for constructing a bottom contact for use with a CBRAM memory element are described. It will be understood that this process, and the bottom contact that is created using it, may be used with a conventional CBRAM element, as well as a CBRAM memory element according to the invention. It will further be recognized that a CBRAM memory element according to the invention is not limited to using a bottom contact constructed by such a process, but may use any suitable bottom contact, constructed by any process now known or later developed.

FIG. 8A shows an oxide layer 802 onto which a nitride etch stop 804 has been deposited, as well as an additional oxide layer 806. As shown in FIG. 8B, a lithographic process and etching is used to create a trench 808 in the oxide layer 806 for the bottom contact.

FIG. 8C shows a conductive material 810, such as W, deposited in the trench 808 of FIG. 8B, and planarized, for example, by a chemical mechanical planarization process.

In FIG. 8D, a nitride/oxide layer 812 has been deposited over the conductive material 810. As shown in FIG. 8E, a lithographic process and etching are used to form a hole 814 in the nitride/oxide layer 812.

Next, as shown in FIG. 8F, the hole 814 is filled with a conductive material, such as TiN/W or another suitable material, and planarized, completing construction of a bottom contact 816. Once the bottom contact has been deposited, a method such as is described above with reference to FIG. 6 may be used to construct a CBRAM memory element in accordance with the invention. This is shown in FIG. 8G, in which a GeS:Ag solid electrolyte layer 820 doped with approximately 1% to 5% Sb, Sn, In, or another suitable material in accordance with an embodiment of the invention has been deposited above the bottom contact 816. An Ag top contact 822 is deposited above the solid electrolyte layer 820. An optional TaN hard mask layer 824 is deposited above the top contact 822.

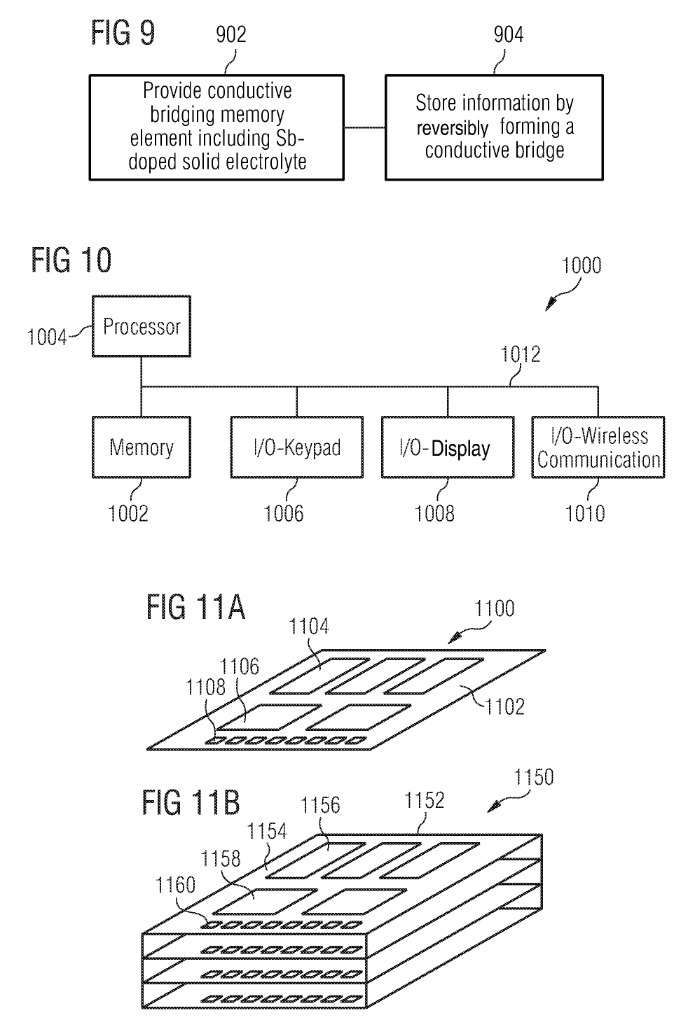

Referring now to FIG. 9, a method of storing information in accordance with the present invention is described. In step 902, a conductive bridging memory element including an Sb-doped solid electrolyte layer, in accordance with the invention, is provided. As discussed above, doping the solid electrolyte layer with Sb, or with another suitable material such as Sn or In will increase the temperature stability of a CBRAM device that includes the doped solid electrolyte layer.

In step 904, information is stored in the conductive bridging memory element by reversibly forming a conductive bridge through the solid electrolyte layer, as described above.

Memory cells such as are described above may be used in memory devices that contain large numbers of such cells. These cells may, for example, be organized into an array of memory cells having numerous rows and columns of cells, each of which stores one or more bits of information. Memory devices of this sort may be used in a variety of applications or systems, such as the illustrative system shown in FIG. 10.

FIG. 10 shows an example computing system that uses a memory device constructed of memory cells in accordance with the invention. The computing system 1000 includes a memory device 1002, which may utilize memory cells having a solid electrolyte layer that is doped with Sb, Sn, In, or another suitable material, to increase the temperature stability of the memory cells in accordance with the invention. The system also includes a processor 1004, and one or more input/output devices, such as a keypad 1006, display 1008, and wireless communication device 1010. The memory device 1002, processor 1004, keypad 1006, display 1008 and wireless communication device 1010 are interconnected by a bus 1012.

The wireless communication device 1010 may include circuitry (not shown) for sending and receiving transmissions over a cellular telephone network, a WiFi wireless network, or other wireless communication network. It will be understood that the variety of input/output devices shown in FIG. 10 is merely an example, in which the computing system 1000 may be configured as a cellular telephone or other wireless communications device. Memory devices including memory cells in accordance with the invention may be used in a wide variety of systems. Alternative system designs may include different input/output devices, multiple processors, alternative bus configurations, and many other configurations.

Memory cells formed in accordance with an embodiment of the invention may be used in a variety of memory devices. As shown in FIGS. 11A and 11B, in some embodiments, memory devices such as those described herein may be used in modules. In FIG. 11A, a memory module 1100 is shown, on which one or more memory devices 1104 are arranged on a substrate 1102. Each memory device 1104 may include memory cells in accordance with an embodiment of the invention. The memory module 1100 may also include one or more electronic devices 1106, which may include memory, processing circuitry, control circuitry, addressing circuitry, bus interconnection circuitry, or other circuitry or electronic devices that may be combined on a module with a memory device 1104. Additionally, the memory module 1100 includes multiple electrical connections 1108, which may be used to connect the memory module 1100 to other electronic components, including other modules. For example, the memory module 1100 may be plugged into a larger circuit board, including PC main boards, video adapters, cell phone circuit boards or portable video or audio players, among others.

As shown in FIG. 11B, in some embodiments, these modules may be stackable, to form a stack 1150. For example, a stackable memory module 1152 may include one or more memory devices 1156, arranged on a stackable substrate 1154. Each of the memory devices 1156 includes a memory array in accordance with an embodiment of the invention. The stackable memory module 1152 also may include one or more electronic devices 1158, which may include memory, processing circuitry, control circuitry, addressing circuitry, bus interconnection circuitry, or other circuitry or electronic devices that may be combined on a module with a memory device 1156. Electrical connections 1160 are used to connect the stackable memory module 1152 with other modules in the stack 1150, or with other electronic devices. Other modules in the stack 1150 may include additional stackable memory modules, similar to the stackable memory module 1152 described above, or other types of stackable modules, such as stackable processing modules, control modules, communication modules, or other modules containing electronic components.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising:
a reactive electrode comprising a metal;
an inert electrode comprising a conductive material; and
a solid electrolyte layer disposed between the reactive electrode and the inert electrode,
wherein the solid electrolyte layer comprises a matrix material having the metal dissolved therein, and a dopant distributed in the matrix material, the solid electrolyte layer configured so that the dopant competes with the metal to bind with elements of the matrix material at a crystallization temperature so that at least a portion of the metal in the matrix material remains unbound.

2. The integrated circuit of claim 1, wherein the dopant comprises antimony, tin, or indium.

3. The integrated circuit of claim 1, wherein the metal comprises silver.

4. The integrated circuit of claim 1, wherein the matrix material comprises a germanium sulfide compound.

5. The integrated circuit of claim 1, wherein the dopant goes into reaction with the matrix material at a temperature at or above a crystallization temperature.

6. The integrated circuit of claim 1, wherein the dopant competes with the metal to bind excess sulfur in the matrix material.

7. The integrated circuit of claim 1, wherein a conductive bridge comprising the metal is reversibly formed through the solid electrolyte layer when a voltage is applied between the reactive electrode and the inert electrode.

8. A method of forming an integrated circuit, the method comprising:
forming a solid electrolyte layer comprising a matrix material and a dopant distributed in the matrix material;
depositing a metal; and
diffusing the metal into the solid electrolyte layer;
wherein forming the solid electrolyte layer comprises configuring the solid electrolyte layer so that the dopant competes with the metal to bind with elements of the matrix material at a crystallization temperature so that at least a portion of the metal in the matrix material remains unbound, to increase temperature stability of a memory element that includes the solid electrolyte layer.

9. The method of claim 8, wherein diffusing the metal comprises using photodiffusion to diffuse the metal into the solid electrolyte layer.

10. The method of claim 8, wherein the solid electrolyte layer is formed above an inert electrode and wherein the method further comprises forming a reactive electrode above a second solid electrolyte layer.

11. The method of claim 8, wherein the dopant comprises antimony, tin, or indium.

12. The method of claim 8, wherein depositing the metal comprises depositing silver.

13. The method of claim 8, wherein the matrix material comprises a germanium sulfide compound.

14. The method of claim 8, wherein the dopant goes into reaction with the matrix material at a temperature at or above the crystallization temperature.

15. The method of claim 8, wherein the dopant competes with the metal to bind excess sulfur in the matrix material.

16. An integrated circuit comprising:
a select transistor; and
a conductive bridging memory element coupled to the select transistor, the conductive bridging memory element comprising an inert electrode, a solid electrolyte layer, and a reactive electrode,
wherein the solid electrolyte layer is disposed between the reactive electrode and the inert electrode, and comprises a matrix material having a metal dissolved therein, and a dopant distributed in the matrix material, the dopant competing with the metal to bind with elements of the matrix material at a crystallization temperature so that at least a portion of the metal in the matrix material remains unbound; and
wherein information is stored by reversibly forming a conductive bridge comprising the metal through the solid electrolyte layer when a voltage is applied between the reactive electrode and the inert electrode.

17. The integrated circuit of claim 16, wherein the dopant comprises antimony, tin, or indium.

18. The integrated circuit of claim 16, wherein the dopant goes into reaction with the matrix material at a temperature at or above the crystallization temperature.

19. The integrated circuit of claim 16, wherein the dopant competes with the metal to bind excess sulfur in the matrix material.

20. A method of storing information, the method comprising:
providing a conductive bridging memory element comprising a solid electrolyte layer that comprises a matrix material having a metal dissolved therein, and a dopant distributed in the matrix material, the dopant competing with the metal to bind with elements of the matrix material at a crystallization temperature so that at least a portion of the metal in the matrix material remains unbound; and
reversibly forming a conductive bridge through the solid electrolyte layer to store information.

21. The method of claim 20, wherein providing the conductive bridging memory element comprises providing the solid electrolyte layer wherein the dopant comprises antimony, tin, or indium.

22. The method of claim 20, wherein providing the conductive bridging memory element comprises providing the solid electrolyte layer wherein the dopant goes into reaction with the matrix material at a temperature at or above the crystallization temperature.

23. The method of claim 20, wherein providing the conductive bridging memory element comprises providing the solid electrolyte layer wherein the dopant competes with the metal to bind excess sulfur in the matrix material.

24. A memory module comprising:
a plurality of integrated circuits, wherein each integrated circuit comprises a plurality of memory elements, each memory element comprising a reactive electrode comprising a metal, an inert electrode comprising a conductive material, and a solid electrolyte layer disposed between the reactive electrode and the inert electrode, wherein the solid electrolyte layer comprises a matrix material having the metal dissolved therein, and a dopant distributed in the matrix material, the solid electrolyte layer configured so that the dopant competes with the metal to bind with elements of the matrix material at a crystallization temperature so that at least a portion of the metal in the matrix material remains unbound, to increase temperature stability of the memory element, wherein the integrated circuits are electrically coupled to form a memory module.
